(19) United States
(12) Patent Application Publication
(10) Pub. No.: US 2005/0181624 A1
(43) Pub. Date: Aug. 18, 2005

(54) Method of forming quantum dots at predetermined positions on a substrate

(75) Inventors: Martin Kammler, Dresden (DE); Frances M. Ross, Stamford, CT (US); Mark C. Reuter, Montrose, NY (US); Robert Hull, Afton, VA (US); Yurii A. Vlasov, Katonah, NY (US); Sharee J. McNab, Mahopac, NY (US)

Correspondence Address: Frank Chau, Esq.;F. CHAU & ASSOCIATES, LLC, Suite 501, 1900 Hempstead Turnpike, East Meadow, NY, 11554, US

(73) Assignee: International Business Machines Corporation

(21) Appl. No.: 10/779,457

(22) Filed: Feb. 13, 2004

(51) Int. Cl. H01L 21/469; H01L 21/31

(52) U.S. Cl. 438/766

(57) ABSTRACT

A method of forming at least one quantum dot on a predetermined area of a substrate includes forming a nucleation site having at least one surface or subsurface defect at the predetermined area of the substrate by implantation with ions, and growing a quantum dot on the nucleation site.

### GOVERNMENT FUNDING

Funding for this invention was provided by the U.S. Government (National Science Foundation) under contract number DMR0080016.

### BACKGROUND

1. Technical Field

The present disclosure relates to control of self-assembled island nucleation during strained layer epitaxial growth.

2. Discussion of Related Art

Small volumes of material (islands) with dimensions in the nanoscale regime (up to several tens of nanometers) can show interesting optical and electronic properties. A common and convenient way to form such islands is to grow a layer of one material epitaxially onto a substrate made of another material which has a slightly different lattice spacing. Under appropriate growth conditions, islands grow spontaneously on the substrate because they allow partial elastic relaxation of the strain in the growing layer (epilayer). This technique is referred to as spontaneous island formation during strained layer epitaxy. The self-assembled islands, or quantum dots, are useful for a range of applications, including electronic devices such as quantum dot lasers, single photon sources, nanocrystal floating-gate memory structures, quantum dot computers and quantum cellular automata. Control of Ge island growth on Si(001) is of particular interest because of the ease of integration of potential devices, made up of Ge quantum dots on a Si substrate, with existing Si-based technology.

In most applications which require quantum dots it is important to have precise control over the size and, to some extent, the shape of the islands, to optimize the properties of the confined electrons. In quantum dot lasers, for example, a wide distribution in island size is undesirable because it translates into a broadening of the emission characteristics, and nanocrystal floating-gate memory structures also require growth of islands which are all of similar sizes. In other applications the position of the islands (their nucleation sites) becomes important, as well as their sizes. Such applications include quantum cellular automata, in which an array consisting of a group of four closely spaced islands must be repeated hundreds of times at predefined locations to form each logic element. Quantum computing applications based on quantum dot structures also require addressable islands, i.e. placed at specific positions (although interestingly they do not all have to be the same size). Finally, perhaps one of the most commercially exciting prospects for quantum dots is their application as a light emission source that can be incorporated onto a Si platform for Si-based opto-electronics. While Si is the dominant material in microelectronics, its indirect bandgap has prohibited its use as a substrate for optical chips. Single quantum dots grown at specific positions within a prefabricated cavity would be required for such applications. Indeed a whole class of optoelectronic structures could be realized if quantum dots could be grown at specific positions on a prepatterned wafer.

Unfortunately, because the islands form spontaneously during strained layer epitaxy, the size distribution and spatial positions of the islands formed using this technique can not be directly controlled. In the Ge/Si(001) system, extensive research has led to a reasonably detailed understanding of the factors which influence island development during strained layer epitaxy. Thus, by appropriate choice of conditions, it is possible to grow Ge islands which are quite narrowly distributed in size and which are dislocation-free. Control of nucleation sites is the most critical remaining issue for applications of Ge islands in devices.

Several methods have already been proposed to control the nucleation sites of islands formed spontaneously during strained layer epitaxy. These methods are briefly discussed below.
(a) Chemical patterning of the substrate: Chemical modification of the surface, for example by partially masking it with an oxide layer, can restrict nucleation sites and therefore allow regular arrays of islands to be formed in the holes within the oxide mask. A disadvantage of this technique is that the mask prevents further epitaxial growth which may be necessary for the device design, such as to encapsulate the islands or to grow stacked layers of islands.
(b) Topographic patterning of the substrate: The formation of mesa structures can similarly control island nucleation sites. Again, however, it is preferable to achieve island patterning using a planar surface to facilitate device design.
(c) Patterning using modulated strain fields: Because self-assembled islands grow as a way to relieve strain, the existence of a surface strain field is expected to control nucleation. Modulated surface strain fields created by, for example, subsurface dislocations are indeed known to control island nucleation and allow rows or arrays of islands to be formed. This technique controls nucleation while preserving the clean, planar Si(001) surface, but unfortunately at present it is difficult to control the positions of the dislocations.

In considering all of these techniques, it is worth emphasizing that a very important feature of an island control technique is whether the nucleation positions can be aligned with an existing pattern on the wafer. Of the example applications given above, single electron transistors, quantum computing and optoelectronic devices require one or more islands to be placed at specific positions on a partly processed wafer. This aspect of patterning is much more challenging than creating an array of islands on a blank wafer. The first two techniques allow alignment to a limited extent but the third does not.

### SUMMARY OF THE INVENTION

A method of forming at least one quantum dot on a predetermined area of a substrate according to an embodiment of the invention includes forming a nucleation site having at least one surface or subsurface defect at the predetermined area of the substrate by implantation with ions, and growing a quantum dot on the nucleation site.

In at least one embodiment of the invention, the quantum dot is grown on the nucleation site by strained layer epitaxy. The implantation of ions is performed using a focused ion beam. The substrate may be annealed after implantation to substantially reduce surface defects.

In at least one embodiment of the invention, the substrate is prepatterned to form at least one prepatterned area, and the location of the nucleation site is determined based on the at least one prepatterned area.

These and other features of the present invention will become apparent from the following detailed description of illustrative embodiments thereof, which is to be read in connection with the accompanying drawings.

### DESCRIPTION OF DRAWINGS

Exemplary embodiments of the invention will be described in detail below with reference to the following figures wherein:

FIGS. 1-4 show steps of a method of forming a patterned array of quantum dots on an unpatterned wafer according to an exemplary embodiment of the invention;

FIGS. 5-9 show steps of a method of forming a patterned array of quantum dots on a prepatterned wafer according to an exemplary embodiment of the invention; and

FIG. 10 is a cross sectional perspective view of a semiconductor waveguide device according to an exemplary embodiment of the invention.

### DESCRIPTION OF PREFERRED EMBODIMENTS

In methods of forming a patterned array of quantum dots according to various exemplary embodiments of the invention, nucleation sites of nanoscale, self-assembled Ge islands on Si(001) can be controlled by patterning the Si surface in situ with a focused ion beam. However, it should be appreciated that the various exemplary embodiments of the invention are applicable to any system where islands grow on a suitable substrate, such as, for example, AlAs islands grown on a GaAs substrate.

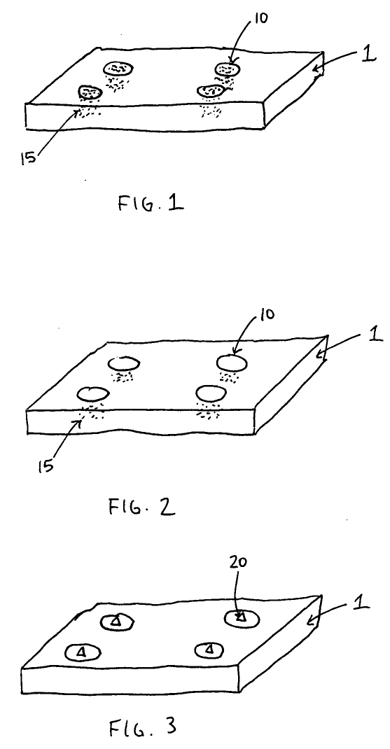

FIGS. 1-4 show steps of a method of forming a patterned array of quantum dots on a blank substrate according to an exemplary embodiment of the present invention. In the present exemplary embodiment of the invention, quantum dots in the form of nanoscale Ge islands are formed on a Si(001) substrate 1. The Si(001) substrate 1 is first degassed and cleaned. The substrate 1 can be cleaned by any suitable cleaning process, such as, for example, repeatedly flashing the substrate 1 to a temperature of about 1250° C. or below.

As shown in FIG. 1, the substrate 1 is patterned by implanting Ga ions with a focused ion beam (FIB). It should be appreciated that in other embodiments of the invention, ions other than Ga ions can be implanted, such as, for example, Si or Au ions, depending on the island/substrate system. The substrate 1 is preferably patterned by centering the substrate 1 beneath a FIB source, such as, for example, a FIB gun, using a scanning electron microscope (SEM) to observe the position of the substrate and a piezoelectric stage to move the substrate into position. As seen in FIG. 1, the pattern includes a series of spots 10 formed using a beam energy in the range of about 1 keV to about 50 keV, a beam current of about 10 pA, and an exposure time in the range of about 10 microsec to about 10 msec. The preferable dose is low, only in the range of about 10¹³ to about 10¹⁶ Ga ions per cm², to optimize precision patterning of the substrate surface and minimize sputtering of the surface. Each spot 10 preferably has a diameter below about 80 nm and forms a nucleation site for subsequent growth of a quantum dot. Ion implantation of Ga ions results in both surface and subsurface defects 15 in the substrate 1.

As shown in FIG. 2, the substrate 1 is then subjected to an annealing process. The substrate 1 is annealed by heating the substrate 1 to a temperature in the range of about 550° C. to about 750° C. The annealing process eliminates most of the damage caused by the ion implantation and restores the surface of the substrate 1 to close to atomic flatness so that little or no topography is present. This annealing process is performed because it improves the alignment of the subsequently grown quantum dots, and can also create a planar surface suitable for subsequent overgrowth. Preferably, some defects, mostly subsurface defects 15, remain after the annealing process. It should be appreciated that in other embodiments of the invention the annealing process may be omitted.

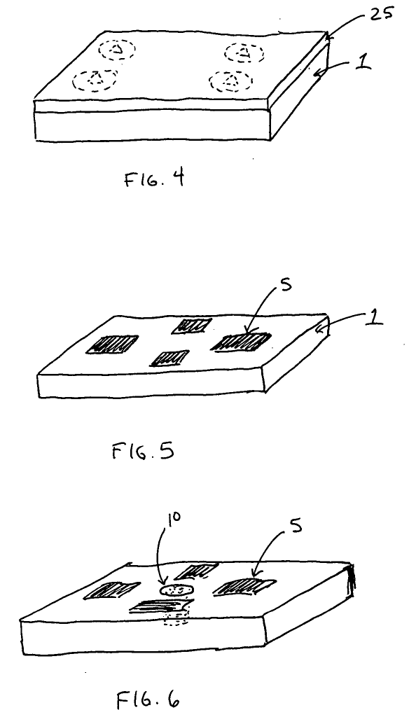

As shown in FIG. 3, Ge islands 20 (quantum dots) are grown on the substrate 1. Ge islands form spontaneously when Ge is deposited epitaxially by any suitable process, such as, for example, chemical vapor deposition or molecular beam epitaxy. Chemical vapor deposition is performed by introducing digermane (Ge₂H₆) gas onto the substrate 1 at a temperature in the range of about 550° C. to about 650° C. and a pressure in the range of about 10⁻⁸ to about 10⁻⁶ Torr. Molecular beam epitaxy is performed by heating the substrate to a similar temperature and exposing it to a flux of Ge atoms from a heated source. Ge deposition leads to spontaneous island nucleation followed by growth and coarsening. An electron microscope can be used to observe island formation and stop Ge growth when islands have formed. If the annealing and deposition conditions are appropriate, every irradiated spot 10 will be occupied by a Ge island 20 with no island growth elsewhere on the substrate 1. The Ge islands 20 may be much smaller than the irradiated spots 10.

As shown in FIG. 4, the Ge islands can be encapsulated to prevent oxidation. In the present exemplary embodiment of the invention, the Ge islands 20 are encapsulated by forming an overgrowth layer 25 over the substrate 1. The overgrowth layer 25 can be made of any suitable material, such as, for example, Si formed by chemical vapor deposition or molecular beam epitaxy.

FIGS. 5-9 shows steps of a method of forming a patterned array of quantum dots on a prepatterned wafer according to an exemplary embodiment of the present invention. In the present exemplary embodiment of the invention, quantum dots in the form of nanoscale Ge islands are formed on a prepatterned Si(001) substrate 1. However, it should be appreciated that the various exemplary embodiments of the invention are applicable to any system where islands grow on a suitable substrate, such as, for example, AlAs islands grown on a prepatterned GaAs substrate. The substrate 1 can be prepatterned by any suitable process, such as, for example, electron-beam lithography or reactive ion etching. As shown in FIG. 5, the prepatterning process produces patterned areas 5 on the wafer 1. The patterned areas 5 shown in FIG. 5 are arranged to define a rectangular area on the substrate 1, but it should be appreciated that in other embodiments of the invention the prepatterned areas 5 can define any suitable shape or array of shapes on the substrate 1. After being prepatterned, the Si(001) substrate 1 is degassed and cleaned. The substrate 1 can be cleaned by any suitable cleaning process which does not affect the prepatterned areas, such as, for example, repeatedly flashing the substrate 1 to a temperature of about 1250° C. or below.

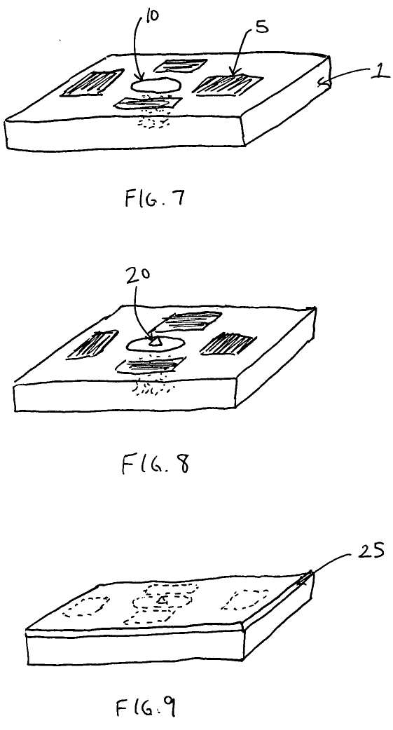

As shown in FIG. 6, the substrate 1 is patterned by implanting Ga ions with a FIB. It should be appreciated that in other embodiments of the invention, ions other than Ga ions can be implanted, such as, for example, Si or Au ions, depending on the island/substrate system. The substrate 1 is preferably patterned by centering the substrate 1 beneath a FIB source, such as, for example, a FIB gun, using a SEM to observe the position of the substrate and a piezoelectric stage to move the substrate into position. The pattern includes a series of spots 10. The SEM can be used to locate the spots 10 in appropriate positions with respect to the prepatterned areas 5 on the substrate 1. The exact positions will depend on the application. The spots 10 are formed using a beam energy in the range of about 1 keV to about 50 keV, a beam current of about 10 pA, and an exposure time in the range of about 10 microsec to about 10 msec. The preferable dose is low, only in the range of about 10¹³ to about 10¹⁶ Ga ions per cm², to optimize precision patterning of the substrate surface and minimize sputtering of the surface. Each spot preferably has a diameter below about 80 nm, and forms a nucleation site for subsequent growth of a quantum dot. Ion implantation of Ga ions results in both surface and subsurface defects 15 in the substrate 1.

As shown in FIG. 7, the substrate 1 is then subjected to an annealing process. The substrate 1 is annealed by heating the substrate 1 to a temperature in the range of about 550° C. to about 750° C. The annealing process eliminates most of the damage caused by the ion implantation and restores the surface of the substrate 1 to close to atomic flatness so that little or no topography is present. This annealing process is performed because it improves the alignment of the subsequently grown quantum dots, and can also create a planar surface suitable for subsequent overgrowth. Preferably, some defects, mostly subsurface defects 15, remain after the annealing process. It should be appreciated that in other embodiments of the invention the annealing process may be omitted.

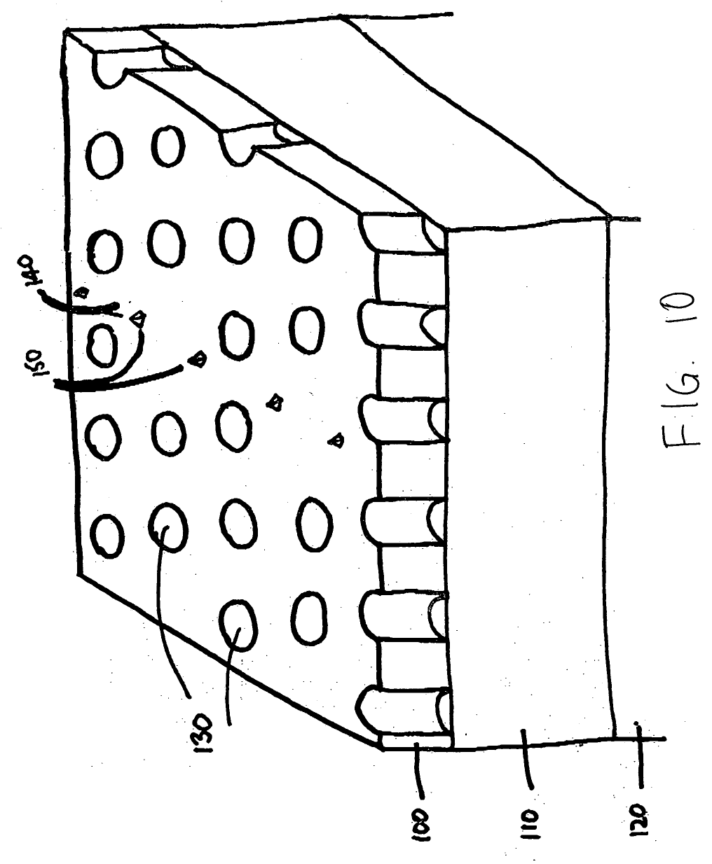

As shown in FIG. 8, Ge islands 20 (quantum dots) are grown on the substrate 1. Ge islands are formed spontaneously when Ge is deposited epitaxially by any suitable process, such as, for example, chemical vapor deposition or molecular beam epitaxy. Chemical vapor deposition is performed by introducing digermane (Ge₂H₆) gas onto the substrate 1 at a temperature in the range of about 550° C. to about 650° C. and a pressure in the range of about 10⁻⁸ to about 10⁻⁶ Torr. Molecular beam epitaxy is performed by heating the substrate to a similar temperature and exposing it to a flux of Ge atoms from a heated source. Ge deposition leads to spontaneous island nucleation followed by growth and coarsening. An electron microscope can be used to observe island formation and stop Ge growth when islands have formed. If the annealing and deposition conditions are appropriate, every irradiated spot 10 will be occupied by a Ge island 20 with no island growth elsewhere on the substrate 1. The Ge islands 20 may be much smaller than the irradiated spots 10. The method according to the present exemplary embodiment of the invention results in Ge islands 20 grown in appropriate positions with respect to the prepatterned areas 5 of a substrate 1.

As shown in FIG. 9, the Ge islands can be encapsulated to prevent oxidation. In the present exemplary embodiment of the invention, the Ge islands 20 are encapsulated by forming an overgrowth layer 25 over the substrate 1. The overgrowth layer 25 can be made of any suitable material, such as, for example, Si formed by chemical vapor deposition or molecular beam epitaxy.

Methods of forming a patterned array of quantum dots on a substrate according to various exemplary embodiments of the present invention can be implemented using an integrated UHV system in which substrate cleaning and heating, FIB irradiation, electron microscopy, and deposition of Ge can all be carried out without breaking vacuum. Experiments using the above-disclosed methods have resulted in the fabrication of arrays of dislocation-free islands composed of Ge having diameters much less than 20 nm. Also, at low doses of 6000 Ga ions per <100 nm spot, the selective growth is achieved without substantially modifying the initial surface topography.

Methods of forming a patterned array of quantum dots on a substrate according to various exemplary embodiments of the present invention can be used in the fabrication of microelectronic devices in which proper positioning of the epitaxial quantum dots on the substrate is critical. Such devices include single electron transistors, and quantum computing and optoelectronic devices. FIG. 10 is a cross-sectional view of a semiconductor waveguide device according to an exemplary embodiment of the invention. The device is formed within a silicon layer 100 on top of a silicon dioxide layer 110 on a silicon wafer 120. The silicon/oxide/silicon layer structure is formed by conventional techniques, such as, for example, wafer bonding or by implantation of oxygen into a silicon wafer followed by annealing. Preferably, the silicon layer 100 is about 200 nm thick, while the oxide layer 110 is about 2000 nm thick.

An array of large holes 130 is formed within the silicon layer 100 by, for example, selective etching through a mask. The holes 130 are about 350 nm in diameter, and spaced about 500 nm apart. The holes 130 are arranged in a plurality of rows, with each hole 130 in a row being shifted a predetermined amount with respect to holes 130 in an adjacent row. A number of rows include areas 140 in which holes 130 are not formed. In other exemplary embodiments of the invention, the holes 130 can have any other size and arrangement such that the array of holes 130 scatters light, and the areas 140 in each row act as a waveguide to channel light through the structure.

An array of Ge quantum dots 150 is formed on the surface of the silicon layer 100 at predetermined positions within the areas 140. The previously disclosed methods can be used to form the array of quantum dots 150. That is, nucleation sites of nanoscale, self-assembled Ge islands on the silicon layer 100 can be controlled by patterning the Si surface in situ with Ga ions, creating a row which is registered with the predefined pattern of the holes 130. The islands can then be encapsulated by covering with a layer of epitaxial silicon (not shown). By controlling the nucleation sites of the Ge quantum dots 150, the quantum dots 150 can be placed at positions of maximum or minimum intensity of the electric field which is set up within the waveguide when light is channeled through it. This can result in either an enhancement or a suppression of the transmission of light through the waveguide, depending on the position of the quantum dots, allowing the device to be used for detection or amplification of light.

Although the device shown in FIG. 10 has only one layer of quantum dots, it should be appreciated that in other embodiments of the invention any number of layers of quantum dots can be formed by depositing multiple silicon epitaxial layers with an array of quantum dots formed over each layer.

Although the illustrative embodiments have been described herein with reference to the accompanying drawings, it is to be understood that the present invention and method are not limited to those precise embodiments, and that various other changes and modifications may be affected therein by one of ordinary skill in the related art without departing from the scope or spirit of the invention. All such changes and modifications are intended to be included within the scope of the invention as defined by the appended claims.

1. A method of forming at least one quantum dot on a predetermined area of a substrate, comprising:
forming a nucleation site comprising at least one surface or subsurface defect at the predetermined area of the substrate by implantation with ions; and
growing a quantum dot on the nucleation site.

2. The method of claim 1, wherein the quantum dot is formed on the nucleation site by strained layer epitaxy.

3. The method of claim 1, wherein the implantation of ions is performed using a focused ion beam.

4. The method of claim 3, wherein the ions are selected from a group consisting of gallium, silicon and gold ions.

5. The method of claim 4, wherein the gallium ions are implanted using a beam energy in a range of about 1 keV to about 50 keV, a beam current of about 10 pA, and an exposure time in a range of about 10 microsec to about 10 msec.

6. The method of claim 4, wherein a dosage of the gallium ions is in a range of about 10¹³ to about 10¹⁶ gallium ions per cm².

7. The method of claim 1, wherein the nucleation site comprises a spot formed on the substrate, and the diameter of the spot is less than about 80 nm.

8. The method of claim 1, further comprising annealing the substrate after implantation.

9. The method of claim 8, wherein the annealing is performed at a temperature in the range of about 550° C. to about 750° C.

10. The method of claim 1, wherein the substrate is a Si substrate.

11. The method of claim 10, wherein the step of growing a quantum dot on the nucleation site comprises growing a Ge island on the Si substrate by strained layer epitaxy.

12. The method of claim 11, wherein the Ge island is grown by introducing digermane gas onto the substrate at a substrate temperature in a range of about 550° C. to about 650° C. and digermane pressure in a range of about 10⁻⁸ Torr to about 10⁻⁶ Torr.

13. The method of claim 1, further comprising encapsulating the quantum dot.

14. The method of claim 13, wherein the step of encapsulating comprises forming an overgrowth layer over the substrate and the quantum dot.

15. The method of claim 1, further comprising:
prepatterning the substrate to form at least one prepatterned area.

16. The method of claim 15, wherein the location of the nucleation site is determined based on the at least one prepatterned area.

17. A method of forming a semiconductor device, comprising:
forming a nucleation site at a predetermined area of a semiconductor device layer by implantation with ions, the nucleation site comprising at least one surface or subsurface defect at the predetermined area; and
growing a quantum dot on the nucleation site.

18. The method of claim 17, wherein the quantum dot is formed on the nucleation site by strained layer epitaxy.

19. The method of claim 17, wherein the semiconductor device is an optoelectronic device.

20. The method of claim 17, wherein the implantation of ions is performed using a focused ion beam.

21. The method of claim 20, wherein the ions are selected from the group consisting of gallium, silicon and gold ions.

22. The method of claim 21, wherein the gallium ions are implanted using a beam energy in a range of about 1 keV to about 50 keV, a beam current of about 10 pA, and an exposure time in a range of about 10 microsec to about 10 msec.

23. The method of claim 21, wherein a dosage of the gallium ions is in a range of about 10¹³ to about 10¹⁶ gallium ions per cm².

24. The method of claim 17, wherein the nucleation site comprises a spot formed on the semiconductor device layer, and the diameter of the spot is less than about 80 nm.

25. The method of claim 17, further comprising annealing the semiconductor device layer after implantation.

26. The method of claim 25, wherein the annealing is performed at a temperature in the range of about 550° C. to about 750° C.

27. The method of claim 17, wherein the substrate is a Si substrate and the step of growing a quantum dot on the nucleation site comprises growing a Ge island on the Si substrate by strained layer epitaxy.

28. The method of claim 27, wherein the Ge island is grown by introducing digermane gas onto the substrate at a substrate temperature in a range of about 550° C. to about 650° C. and digermane pressure in a range of about 10⁻⁸ Torr to about 10⁻⁶ Torr.

29. The method of claim 17, further comprising encapsulating the quantum dot.

30. The method of claim 29, wherein the step of encapsulating comprises forming an overgrowth layer over the semiconductor device layer and the quantum dot.

31. The method of claim 17, further comprising:
prepatterning the semiconductor device layer to form at least one prepatterned area.

32. The method of claim 31, wherein the location of the nucleation site is determined based on the at least one prepatterned area.
